(19) United States
(12) Patent Application Publication
(10) Pub. No.: US 2023/0053018 A1
(43) Pub. Date: Feb. 16, 2023

(54) FOLDABLE SCREENS AND DISPLAY APPARATUSES

(71) Applicants: Chengdu BOE Optoelectronics Technology Co., Ltd., Chengdu, Sichuan (CN); BOE Technology Group Co., Ltd., Beijing (CN)

(72) Inventors: Wei GONG, Beijing (CN); Miao LUO, Beijing (CN); Renzhe XU, Beijing (CN); Haotian YANG, Beijing (CN); Yiming WANG, Beijing (CN); Danyang BI, Beijing (CN); Xiaoxia LIU, Beijing (CN)

(21) Appl. No.: 17/784,383

(22) PCT Filed: Jun. 10, 2021
(86) PCT No.: PCT/CN2021/099396

§ 371 Date: Jun. 10, 2022

(30) Foreign Application Priority Data
Jun. 24, 2020 (CN) 202010591908.X

(51) Int. Cl. G06F 1/20; G06F 1/16

(52) U.S. Cl. CPC G06F 1/203; G06F 1/1641; G06F 1/1652

(57) ABSTRACT

A foldable screen comprises a plurality of display regions spaced apart in a first direction and one or more foldable regions located between two adjacent ones of the display regions, the foldable screen further comprising a supporting layer and a heat dissipation layer arranged in a stack, where the supporting layer is bendable and is arranged in the display regions and the foldable regions; and the heat dissipation layer is bendable and is arranged in the display regions and the folding regions, and portions of the heat dissipation layer corresponding to the foldable regions are provided with through hole arrays. A display device comprising the foldable screen is further disclosed.

The present disclosure claims priority to the Chinese Patent Application No. 202010591908.X entitled “Foldable Screen and Display Apparatus”, filed with the Chinese Patent Office on Jun. 24, 2020, which is incorporated herein by reference in its entirety.

### TECHNICAL FIELD

Embodiments of the present disclosure relate to foldable screens and display apparatuses.

### BACKGROUND

In technologies known by the inventor, a foldable mobile phone module has a relatively thin thickness. To ensure foldable performances, stainless steel is often selected as a supporting layer of the module structure. Stainless steel itself has poor heat dissipation properties and copper foil or graphite sheets may be provided for assisting heat dissipation. Since conventional graphite sheets do not have bendable properties, the graphite sheets can only be disposed in a non-foldable region (e.g., a display region) and cannot be disposed in a foldable region. Therefore, areas contact to graphite are greatly reduced, and thus the heat dissipation properties of the screen are greatly reduced.

### SUMMARY

At least one embodiment of the present disclosure provides a foldable screen, comprising a plurality of display regions spaced apart in a first direction and one or more foldable regions located between two adjacent ones of the display regions, the foldable screen further comprising a supporting layer and a heat dissipation layer arranged in a stack, wherein, the supporting layer is bendable and is arranged in the display regions and the foldable regions; and the heat dissipation layer is bendable and is arranged in the display regions and the folding regions, and portions of the heat dissipation layer corresponding to the foldable regions are provided with through hole arrays.

In an embodiment of the present disclosure, the through hole arrays comprise a plurality of rows of through holes spaced apart along the first direction, each row of the plurality of rows of through holes comprising a plurality of through holes arranged in a second direction, each of the plurality of through holes having a first length in the first direction and having a second length in the second direction, where the first direction is perpendicular to the second direction.

In an embodiment of the present disclosure, the through holes in two adjacent rows are offset from each other.

In an embodiment of the present disclosure, in two adjacent rows of the through holes, lines extending in the first direction through centers of the through holes in a first row pass through a midpoint of a line between centers of two adjacent through holes in a second row.

In an embodiment of the present disclosure, the second length is 10 to 20 times of the first length.

In an embodiment of the present disclosure, a spacing between two adjacent rows of the through holes is 0.5 to 1 time of the first length.

In an embodiment of the present disclosure, a spacing between two adjacent ones of the through holes in a same row is 1 to 1.5 times of the first length.

In an embodiment of the present disclosure, the through holes are in shape of rectangle and corners of the rectangle are rounded.

In an embodiment of the present disclosure, the supporting layer is made of stainless steel and the heat dissipation layer is made of graphene.

In an embodiment of the present disclosure, the foldable screen further comprises:

a buffer layer disposed on a side of the supporting layer away from the heat dissipation layer;

an adhesive layer disposed between the supporting layer and the heat dissipation layer; and

a protection layer disposed on a side of the heat dissipation layer away from the supporting layer.

In an embodiment of the present disclosure, the buffer layer is made of foam.

In an embodiment of the present disclosure, the foldable screen further comprises a flexible display substrate and a cover plate sequentially stacked on the buffer layer.

In an embodiment of the present disclosure, the foldable screen further comprises a polarizer disposed between the flexible display substrate and the cover plate.

At least one embodiment of the present disclosure provides a display device comprising a foldable screen as described above.

The foldable screen and the display device according to the above embodiments can greatly improve the overall heat dissipation performances of the foldable screen by disposing the heat dissipation layer capable of folding or unfolding in both the display regions and the foldable regions; further, the folding property of the entire module can be effectively ensured by disposing the heat dissipation layer in the foldable region with an array of through holes.

### BRIEF DESCRIPTION OF THE DRAWINGS

FIG. 1 shows a partial sectional structural schematic diagram of a foldable screen according to an exemplary embodiment of the present disclosure.

FIG. 2 shows a partial top view structural schematic diagram of a foldable screen according to an exemplary embodiment of the present disclosure.

FIG. 3 shows a partial enlarged view of part B in FIG. 2.

FIG. 4 shows a partial perspective structural schematic diagram of a foldable screen according to an exemplary embodiment of the present disclosure.

FIG. 5 shows a partial sectional structural schematic diagram of a foldable screen taken in another angle according to an exemplary embodiment of the present disclosure.

### REFERENCE NUMERAL DESCRIPTION

Foldable screen 1
Display region A1
Foldable region A2
Supporting layer 10
Heat dissipation layer 11
through hole 111
Buffer layer 12
Adhesive layer 13
Protection layer 14
Flexible display substrate 15
Cover plate 16
Polarizer 17
Glue Layer 18
Back film 19
First direction L1
Second direction L2
First length s1
Second length s2
A spacing s3 between two adjacent rows of through holes
A spacing s4 between two adjacent through holes in the same row

### DETAILED DESCRIPTION OF THE EMBODIMENTS

Reference will be made herein in detail to exemplary embodiments, examples of which are illustrated in the accompanying drawings. The following description relates to the accompanying drawings in which the same numbers in different drawings represent the same or similar elements unless otherwise represented. The implementations described in the following exemplary embodiments do not represent all implementations consistent with the present disclosure. Instead, they are merely examples of devices consistent with some aspects of the present disclosure as detailed in the appended claims.

The terminology used herein is for the purpose of describing particular embodiments only and is not intended to be limiting of the disclosure. Unless defined otherwise, technical or scientific terms used herein have the same meaning as is commonly understood by one of ordinary skill in the art to which this disclosure belongs. The use of “a”, “an” or the like in the description and in the claims of the disclosure also does not denote a limitation of quantity, but rather denotes the presence of at least one of the referenced items. The term “including”, “comprising” or the like indicates that elements or articles preceding “comprising” or “comprises” encompass elements or articles listed thereafter and equivalents thereof and not exclusive of other elements or articles. The term “connected”, “coupled” or the like is not restricted to physical or mechanical connections, and may include electrical connections, regardless of direct or indirect connections. As used in the description and the appended claims of the present disclosure, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

At least one embodiment of the present disclosure provides a foldable screen 1. As shown in FIG. 1, the foldable screen 1 includes a supporting layer 10 and a heat dissipation layer 11 arranged in a stack, both of which can be foldable, with a projection of the heat dissipation layer 11 onto the supporting layer 10 being located within the supporting layer 10.

The foldable screen 1 includes two display regions A1 which are spaced apart, and a foldable region A2 located between the two display regions A1 along a first direction L1, where the supporting layer 10 and the heat dissipation layer 11 are disposed in each of the display regions A1 and the foldable region A2, and the heat dissipation layer 11 disposed in the foldable region A2 is provided with through holes 111 arranged in an array. In this way, by providing the foldable heat dissipation layer 11 in the display regions Al and the folding region A2, the overall heat dissipation performances of the foldable screen 1 can be greatly enhanced; further, by providing the heat dissipation layer 11 in the foldable region A2 with the through holes 111 arranged in an array, the foldable property of the overall structure can be effectively ensured, and the overall structure has excellent folding performance.

It should be noted that, depending on design requirements, a number of the display regions A1 spaced apart, included in the foldable screen 1 along the first direction L1 may be three, or four or other numbers, and accordingly, a number of the foldable regions A2 between two adjacent display regions A1 along the first direction L1 may be adjusted according to the number of the display regions A1.

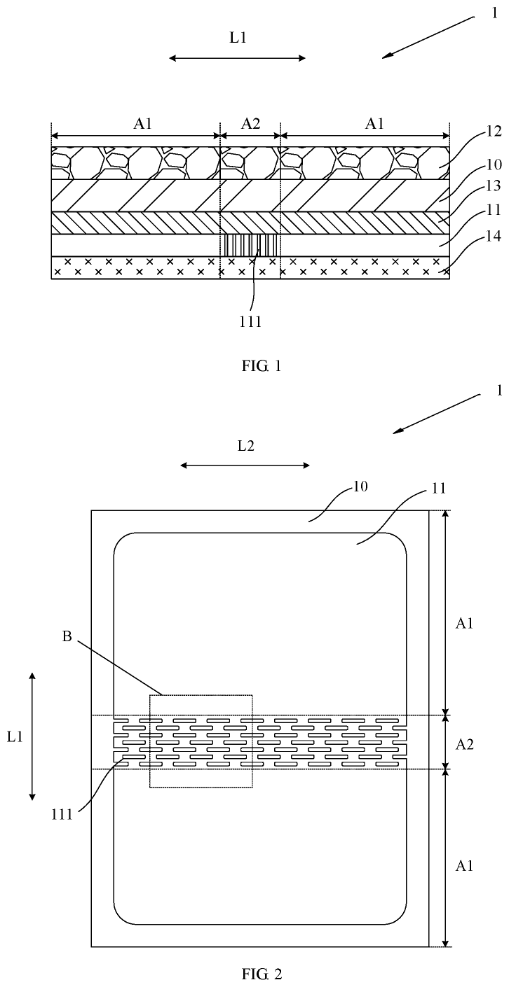

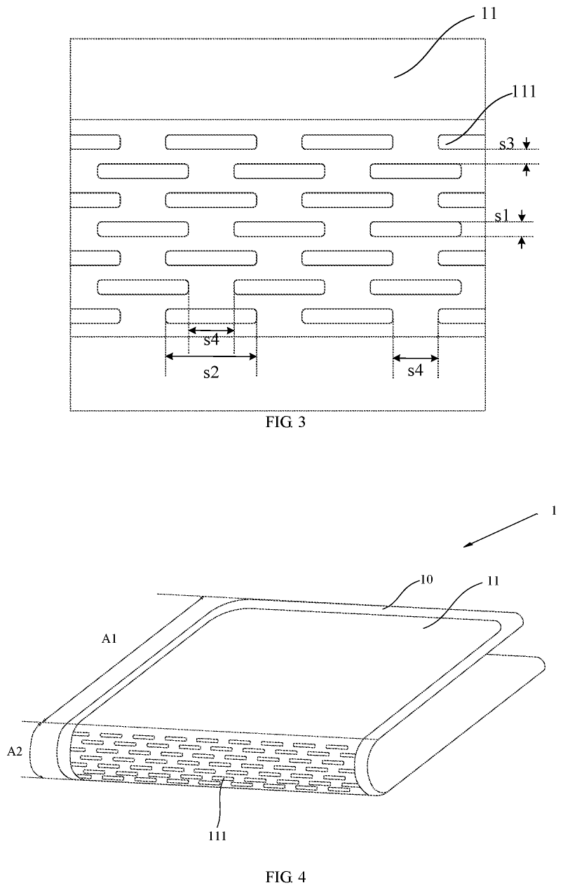

As shown in FIGS. 2 and 3, the through holes 111 arranged in an array are arranged as follows: a plurality of rows of through holes 111 are spaced apart along the first direction L1, and a plurality of through holes 111 are spaced apart along a second direction L2 perpendicular to the first direction L1. The through holes 111 in two adjacent rows are offset from each other to distribute the applied stress. In an embodiment of the present disclosure, among first row of through holes 111 and second row of through holes 111 adjacent to each other, lines extending in the first direction through centers of the through holes 111 in the first row pass through a midpoint of a line between centers of the two adjacent through holes 111 in the second row.

A length of the through holes 111 in the first direction L1 is a first length s1, and a length of the through holes 111 in the second direction L2 is a second length s2. A spacing between adjacent rows is s3 and a distance between adjacent through holes in the same row is s4. The through holes 111 may have a regular shape such as a rectangle, oval, diamond, rounded rectangle, regular polygon, or the like. Alternatively, the through holes 111 may have an irregular shape. In an embodiment of the present disclosure, the through holes 111 are rectangular to facilitate machining; corners of the rectangle are rounded to prevent stress concentration.

Regardless of shapes of the through holes 111, the first length s1 of the through holes 111 is a maximum length of a shape along the first direction L1, and a second length s2 of the through holes 111 is a maximum length of the shape along the second direction L2.

In some embodiments of the present disclosure, the second length s2 of the through holes 111 is greater than or equal to 10 times the first length s1. The spacing s3 between two adjacent rows of through holes 111 is less than or equal to the first length s1. The spacing s4 between two adjacent through holes 111 in the same row is greater than or equal to the first length s1.

In some embodiments of the present disclosure, the second length s2 of the through holes 111 is 10 to 20 times of the first length s1. The spacing s3 between two adjacent rows of through holes 111 is 0.5 to 1 time of the first length s1. The spacing s4 between two adjacent through holes 111 in the same row is 1 to 1.5 times of the first length s1. In this way, the heat dissipation layer 11 can have better folding performance by adjusting dimensions and spacings of the through holes 111.

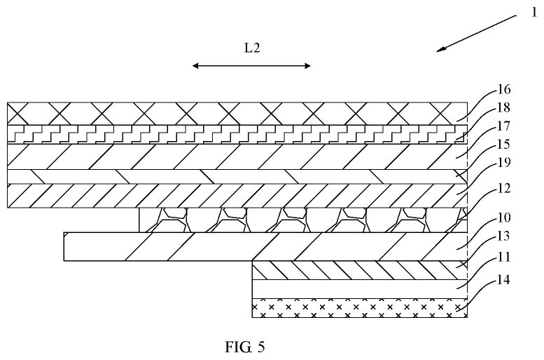

It should be noted that, to show the structure of the through holes 111 more clearly, only the supporting layer 10 and the heat dissipation layer 11 are shown in FIGS. 2, 3 and 4 without including other layer structures thereon.

In some embodiments of the present disclosure, a material of the supporting layer 10 is stainless steel. A material of the heat dissipation layer 11 is graphene, which has a small thickness and excellent heat dissipation performance. However, the material of the supporting layer 10 may be another material having a supporting function and being bendable, and similarly the material of the heat dissipation layer 11 may be another material having a heat dissipating function and being bendable.

In some embodiments of the present disclosure, the foldable screen 1 further includes a buffer layer 12, an adhesive layer 13, and a protection layer 14. The buffer layer 12 is located on a side of the supporting layer 10 away from the heat dissipation layer 11. The adhesive layer 13 is located between the supporting layer 10 and the heat dissipation layer 11. The protection layer 14 is located on a side of the heat dissipation layer 11 away from the supporting layer 10.

In some embodiments of the present disclosure, as shown in FIG. 5, the foldable screen 1 further includes a flexible display substrate 15 and a cover plate 16 stacked on the buffer layer 12. A polarizer 17 is further provided between the flexible display substrate 15 and the cover plate 16 and is attached/laminated to the cover plate 16 through a glue layer 18. A back film 19 is further provided between the flexible display substrate 15 and the buffer layer 12, and planarizes the flexible display substrate 15.

The buffer layer 12 has some shock absorption and buffering effect, and the buffer layer 12 can also laminate/attach the layer structure thereunder to the flexible display substrate 15 thereabove. The buffer layer 12 may be made of foam. Since the buffer layer 12, the supporting layer 10, and the heat dissipation layer 11 are usually combined firstly and then laminating is performed through the buffer layer 12, no additional process is added in the subsequent laminating process.

The protection layer 14 is made of polyethylene terephthalate (PET) and is configured to protect the heat dissipation layer 11.

The heat dissipation layer 11 and the supporting layer 10 are attached/laminated by the adhesive layer 13, which may be made of an optical adhesive. Similarly, the glue layer 18 may be made of an optical adhesive.

At least one embodiment of the present disclosure further provides a display device including the foldable screen 1 described above.

The foregoing description is only exemplary embodiments of the disclosure and is not to be construed as limiting the disclosure. Any modification, equivalent replacement, improvement or the like. made within spirits and principles of this disclosure shall be included in the scope of protection of this disclosure.

1. A foldable screen, comprising a plurality of display regions spaced apart in a first direction and one or more foldable regions located between two adjacent ones of the display regions, the foldable screen further comprising a supporting layer and a heat dissipation layer arranged in a stack, wherein,
the supporting layer is bendable and is arranged in the display regions and the foldable regions; and
the heat dissipation layer is bendable and is arranged in the display regions and the folding regions, and portions of the heat dissipation layer corresponding to the foldable regions are provided with through hole arrays.

2. The foldable screen according to claim 1, wherein the through hole arrays comprise a plurality of rows of through holes spaced apart along the first direction, each row of the plurality of rows of through holes comprising a plurality of through holes arranged in a second direction, each of the plurality of through holes having a first length in the first direction and having a second length in the second direction, wherein the first direction is perpendicular to the second direction.

3. The foldable screen according to claim 2, wherein the through holes in two adjacent rows in a plurality of rows of through holes are offset from each other.

4. The foldable screen according to claim 2, wherein, in two adjacent rows of the through holes, lines extending in the first direction through centers of the through holes in a first row pass through a midpoint of a line between centers of two adjacent through holes in a second row.

5. The foldable screen according to claim 2, wherein the second length is 10 to 20 times of the first length.

6. The foldable screen according to any claim 2, wherein a spacing between two adjacent rows of the through holes is 0.5 to 1 time of the first length.

7. The foldable screen according to claim 2, wherein a spacing between two adjacent ones of the through holes in a same row is 1 to 1.5 times of the first length.

8. The foldable screen according to claim 1, wherein the through holes are in shape of rectangle and corners of the rectangle are rounded.

9. The foldable screen according to claim 1, wherein the supporting layer is made of stainless steel and the heat dissipation layer is made of graphene.

10. The foldable screen according to claim 1, further comprising:
a buffer layer disposed on a side of the supporting layer away from the heat dissipation layer;
an adhesive layer disposed between the supporting layer and the heat dissipation layer; and
a protection layer disposed on a side of the heat dissipation layer away from the supporting layer.

11. The foldable screen according to claim 10, wherein the buffer layer is made of foam.

12. The foldable screen according to claim 10, further comprising a flexible display substrate and a cover plate sequentially stacked on the buffer layer.

13. The foldable screen according to claim 12, further comprising a polarizer disposed between the flexible display substrate and the cover plate.

14. A display device comprising a foldable screen according to claim 1.

15. The foldable screen according to claim 13, wherein the polarizer is attached to the cover plate through a glue layer.

16. The foldable screen according to claim 15, wherein the glue layer is made of an optical adhesive.

17. The foldable screen according to claim 10, wherein the adhesive layer is made of an optical adhesive.

18. The foldable screen according to claim 10, wherein the protection layer is made of polyethylene terephthalate.

19. The foldable screen according to claim 12, further comprising a back film disposed between the flexible display substrate and the buffer layer.

20. The foldable screen according to claim 10, wherein the protection layer is configured to protect the heat dissipation layer.
